(19) United States
(12) Patent Application Publication
(10) Pub. No.: US 2014/0198437 A1
(43) Pub. Date: Jul. 17, 2014

(54) Method for Use of Continuous Biocomposite Fiber Reinforced Polymer in an Information Handling System Chassis

(71) Applicant: DELL PRODUCTS, LP, Round Rock, TX (US)

(72) Inventors: B. Bryce Busby, Round Rock, TX (US); Deeder M. Aurongzeb, Round Rock, TX (US)

(73) Assignee: DELL PRODUCTS, LP, Round Rock, TX (US)

(21) Appl. No.: 13/739,574

(22) Filed: Jan. 11, 2013

(51) Int. Cl. H05K 5/03; B27J 1/00; G06F 1/16

(52) U.S. Cl. CPC H05K 5/03; G06F 1/16; B27J 1/00
USPC 361/679.02; 144/333; 312/223.1

(57) ABSTRACT

A method of providing a case for an information handling system includes placing a first fiber layer into a form, where the first fiber layer is prepregnated with a matrix material, applying a bonding material to the first fiber layer, placing a bamboo layer into the form on top of the first fiber layer, wherein the bamboo layer is prepregnated with the matrix material, applying the bonding material to the bamboo layer, placing a second fiber layer into the form on top of the bamboo layer, wherein the second fiber layer is prepregnated with the matrix material, and curing the contents of the form a portion of the case.

### FIELD OF THE DISCLOSURE

This disclosure relates generally to information handling systems, and relates more particularly to the use of continuous bamboo fiber reinforced polymer in an information handling system chassis.

### BACKGROUND

As the value and use of information continues to increase, individuals and businesses seek additional ways to process and store information. One option is an information handling system. An information handling system generally processes, compiles, stores, or communicates information or data for business, personal, or other purposes. Because technology and information handling needs and requirements can vary between different applications, information handling systems can also vary regarding what information is handled, how the information is handled, how much information is processed, stored, or communicated, and how quickly and efficiently the information can be processed, stored, or communicated. The variations in information handling systems allow information handling systems to be general or configured for a specific user or specific use such as financial transaction processing, airline reservations, enterprise data storage, or global communications. In addition, information handling systems can include a variety of hardware and software resources that can be configured to process, store, and communicate information and can include one or more computer systems, data storage systems, and networking systems.

### BRIEF DESCRIPTION OF THE DRAWINGS

It will be appreciated that for simplicity and clarity of illustration, elements illustrated in the Figures have not necessarily been drawn to scale. For example, the dimensions of some of the elements are exaggerated relative to other elements. Embodiments incorporating teachings of the present disclosure are shown and described with respect to the drawings presented herein, in which:

FIG. 1 illustrates an information handling system according to an embodiment of the present disclosure;

FIG. 2 illustrates a base portion of a chassis of the information handling system of FIG. 1;

FIG. 3 illustrates a cross section of a chassis bottom of the base portion of the chassis of FIG. 2;

FIG. 4 illustrates a sectional view of the chassis bottom of FIG. 3;

FIG. 5 is a flow chart illustrating a method of using continuous bamboo fiber reinforced polymer in an information handling system chassis according to an embodiment of the present disclosure; and

FIG. 6 is a block diagram of an information handling system according to an embodiment of the present disclosure.

The use of the same reference symbols in different drawings indicates similar or identical items.

### DETAILED DESCRIPTION OF DRAWINGS

The following description in combination with the Figures is provided to assist in understanding the teachings disclosed herein, and will focus on specific implementations and embodiments of the teachings. This focus is provided to assist in describing the teachings, and should not be interpreted as a limitation on the scope or applicability of the teachings. Other teachings can be used in conjunction with this application, and the teachings herein can be used in other applications, and with different types of structures and architectures.

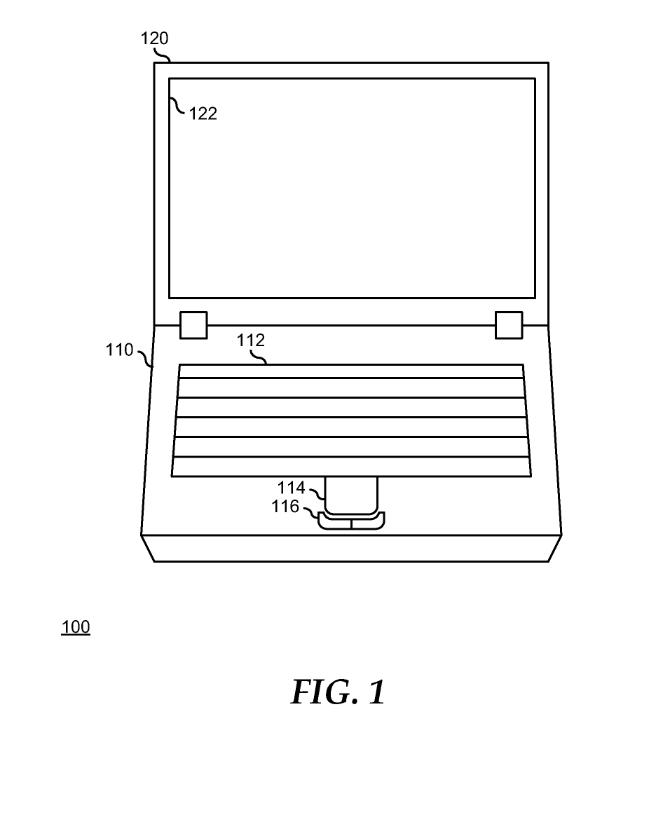

FIG. 1 illustrates an information handling system 100. For purpose of this disclosure, an information handling system may include any instrumentality or aggregate of instrumentalities operable to compute, classify, process, transmit, receive, retrieve, originate, switch, store, display, manifest, detect, record, reproduce, handle, or utilize any form of information, intelligence, or data for business, scientific, control, entertainment, or other purposes. For example, an information handling system may be a personal computer, a cellular telephone, a smart phone, a tablet computer, a consumer electronic device, a network server or storage device, a switch router or other network communication device, or any other suitable device and may vary in size, shape, performance, functionality, and price. The information handling system may include memory, one or more processing resources such as a central processing unit (CPU) or hardware or software control logic, and operates to execute code. Additional components of the information handling system may include one or more storage devices that can store code, one or more communications ports for communicating with external devices as well as various input and output (I/O) devices, such as a keyboard, a mouse, and a video display. The information handling system may also include one or more buses operable to transmit communications between the various hardware components. A illustrated here, information handling system is represented by a laptop computer system, however the teachings disclosed herein are generally applicable to other types of information handling systems.

Information handling system 100 includes a base 110 and a lid 120. Base 110 houses one or more portions of the mechanisms that perform the functions of information handling system 100, such as electronic circuit boards, disk drives, sockets and connectors for power or to connect to other devices, and interface devices such as a keyboard 112, a touchpad device 114, and function buttons 116. Lid 120 houses other portions of the mechanisms that perform the functions of information handling system 100, such as wireless communications (WiFi) antennas, indicators, and a display 122.

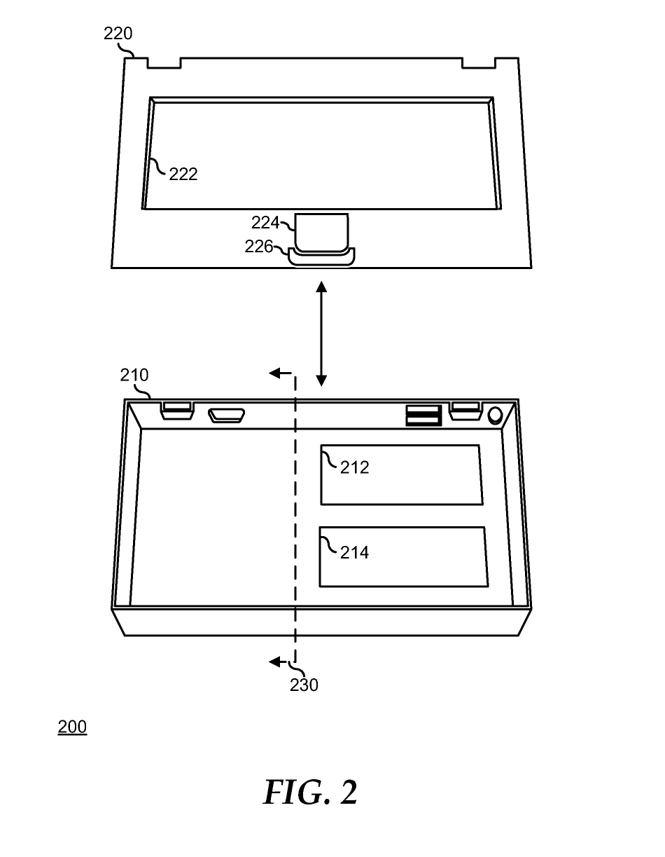

FIG. 2 illustrates base portion 200 of a chassis for information handling system 100, including a chassis bottom 210 and a chassis bottom cover 220. Chassis bottom 210 provides fastening locations for mounting the mechanisms housed in base 110, and includes various openings to accommodate the sockets and connections. In addition, chassis bottom 210 includes a hard-drive opening 212 and a battery opening 214. Hard-drive opening 212 and battery opening 214 are configured to accept respective covers and are operable to permit a user of information handling system 100 to access a hard-drive and a battery for service, repair, or replacement of the respective components within the information handling system. Chassis bottom cover 220 provides fastening locations for attaching the bottom cover to chassis bottom 210 for the purpose of enclosing the mechanisms housed in base 110. Chassis bottom cover 220 includes a keyboard opening 222, a touchpad device opening 224, and a function button opening 226, for allowing the respective keyboard 112, touchpad 114, and function buttons 116 to protrude through the bottom cover.

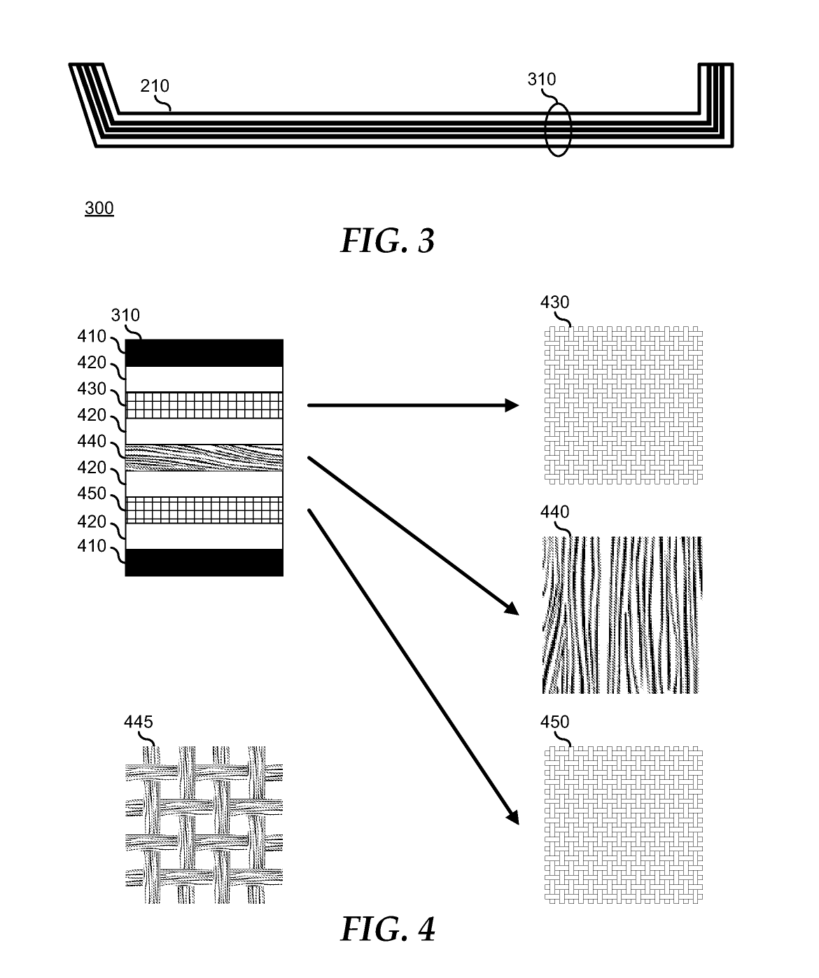

FIG. 3 illustrates a cut-away view 300 of chassis bottom 210. Cut-away view 300 is a view along cross-section 230 of FIG. 2, and illustrates that chassis bottom 210 is constructed using a layered composite construction technique as shown in section 310. As such, chassis bottom 210 is constructed by layering various prepregnated fiber materials with a matrix material, placing the prepregnated fiber materials in a mould and curing the mould to form the desired shape of the bottom housing. In a particular embodiment, the matrix material includes a polymer or resin matrix material, and can be a thermoplastic matrix or a thermosetting matrix material. For example, the matrix material can include an epoxy resin, a phenolic resin, polyester resin, vinyl ester resin, another matrix material, or a combination thereof. The fiber materials can include glass fiber, carbon fiber, aramid fiber, natural fiber, or another type of fiber that is prepregnated with the matrix material. The fiber materials can be strands of the fiber material, a woven fabric of the fiber material, or a combination thereof. The skilled artisan will recognize that there are several methods of prepregnating the fiber material, including a hot melt prepregnation process, a solvent dip prepregnation process, another prepregnation process, or a combination thereof. In addition to the prepregnated fiber materials, construction of chassis bottom 210 includes a layer of prepregnated bamboo, as described further, below. The moulding process can include a vacuum bag or pressure bag moulding process, a press moulding process, another moulding process, or a combination thereof, as needed or desired.

FIG. 4 illustrates section 310 including an outer layer 410, a bonding material 420, a fiber layer 430, a bamboo layer 440, and another fiber layer 450. The bonding material 420 is between a top portion of outer layer 410 and fiber layer 430, between fiber layer 430 and bamboo layer 440, between bamboo layer 440 and fiber layer 450, and between fiber layer 450 and a bottom portion of outer layer 410. In a particular embodiment, outer layer 410 provides a tough and visually appealing outer finish to section 310. In another embodiment, outer layer 410 provides a decorative finish, such as an in-mold release, an in-mold label, a spray painting, a physical vapor deposition, a sputter plating, a paint film, or another decorative finish, as needed or desired. Bonding material 420 includes a matrix material that, when cured or treated, bonds the layers together. Fiber layers 430 and 450 are prepregnated with matrix material, and are represented here as woven fabrics of the fiber material. In a particular embodiment, one or more of fiber layers 430 and 450 are made up of bundles of continuous filaments that provide a unidirectional reinforcement to section 310. For example, fiber layer 430 can include prepregnated bundles of filaments that are laid out in a first direction, and fiber layers 450 can include prepregnated bundles of filaments that are laid out perpendicularly to the filaments of fiber layer 430. In another embodiment, one or more additional layers of prepregnated fiber material are included in section 310.

Bamboo layer 440 is prepregnated with matrix material and provides stiffness and rigidity to section 310, and by extension to chassis bottom 210. Bamboo layer 440 is prepregnated with matrix material, and is represented here as a thin sheet of bamboo. In a particular embodiment, section 310 can include one or more additional layers of bamboo, and the layers can be laid out such that the grain pattern in the bamboo sheets are perpendicular to each other, such that the grain pattern in the bamboo sheets are parallel to each other, or in another configuration. In another embodiment, bamboo mat 445 is a woven mat of bamboo slats or fibers that are prepregnated with matrix material and incorporated into section 310, either in addition to bamboo layer 440, or as a substitute for the bamboo layer. In a particular embodiment, the material used to prepregnate one or more of fiber layers 430 and 450 and bamboo layer 440 is the same material as used for bonding material 420.

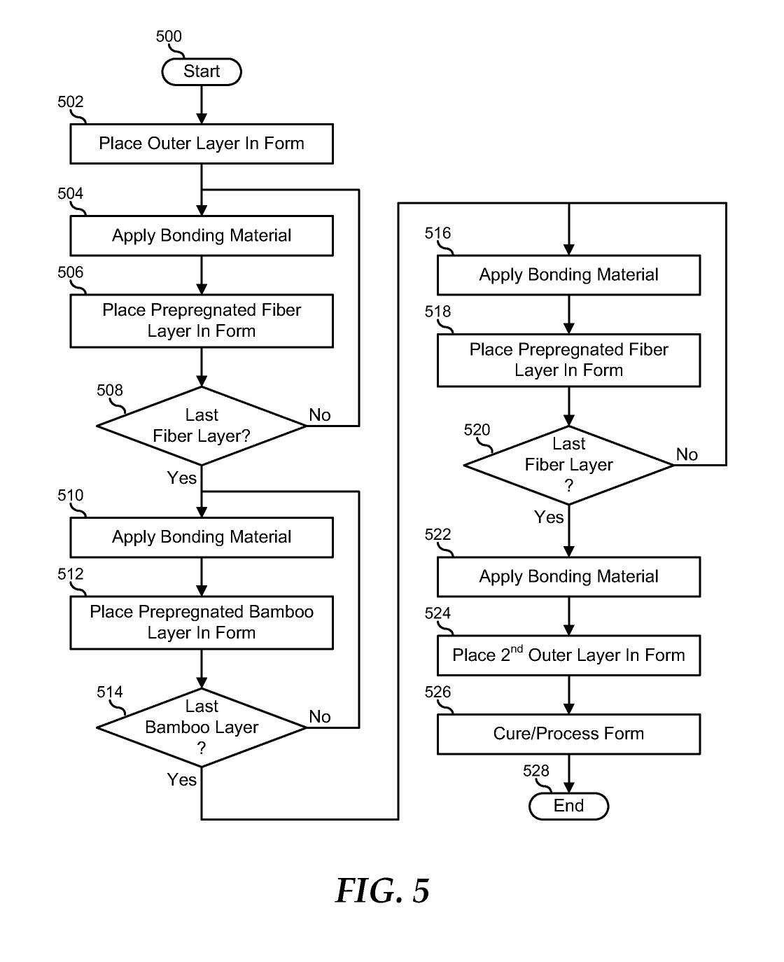

FIG. 5 illustrates a method for using continuous bamboo fiber reinforced polymer in an information handling system chassis, starting at block 500. An outer layer of a case for an information handling system is placed into a form in block 502. For example, a bottom portion of outer layer 410 can be placed into a form for chassis bottom 210. A bonding material is applied to the outer layer on block 504. For example, bonding material 420 can be applied to outer layer 410. A prepregnated fiber layer is placed into the form in block 506. Here, fiber layer 450 can be placed on top of outer layer 410. A decision is made as to whether or not the fiber layer placed in the form is the last fiber layer to be place before adding the bamboo layers in decision block 508. If not, the “NO” branch of decision block 508 is taken and the method returns to block 504 where the bonding material is applied to the fiber layer. In a particular embodiment, each layer is prepregnated with matrix material prior to placement into the form. In another embodiment, the layers are provided in a lamination of layers prior to placement into the form.

If the fiber layer is the last fiber layer to be place before adding the bamboo layer, the “YES” branch of decision block 508 is taken, and the bonding material is applied to the last fiber layer on block 510. For example, bonding material 420 can be applied to outer layer 410. A prepregnated bamboo layer is placed into the form in block 512. Here, bamboo layer 440 can be placed on top of fiber layer 430. A decision is made as to whether or not the bamboo layer placed in the form is the last bamboo layer to be place before adding the additional fiber layers in decision block 514. If not, the “NO” branch of decision block 514 is taken and the method returns to block 510 where the bonding material is applied to the bamboo layer.

If the bamboo layer is the last bamboo layer to be place before adding the additional fiber layers, the “YES” branch of decision block 514 is taken, and the bonding material is applied to the last bamboo layer on block 516. A prepregnated fiber layer is placed into the form in block 518. Here, fiber layer 430 can be placed on top of bamboo layer 440. A decision is made as to whether or not the fiber layer placed in the form is the last fiber layer to be place before adding a second outer layers in decision block 520. If not, the “NO” branch of decision block 520 is taken and the method returns to block 516 where the bonding material is applied to the fiber layer.

If the fiber layer is the last fiber layer to be place before adding the second outer layer, the “YES” branch of decision block 520 is taken, and the bonding material is applied to the last fiber layer on block 522. The second outer layer is placed into the form in block 524. Here, outer layer 410 can be placed on top of fiber layer 430. The form is cured and processed as needed or desired in block 526, and the method ends in block 528. For example, the form with the layers can be pressure treated, heat treated, chemically treated, subjected to another treatment, or a combination thereof. The skilled artisan will recognize that, although the method is described in terms of the layer arrangement of section 310, other arrangements and layering orders can be performed as needed or desired.

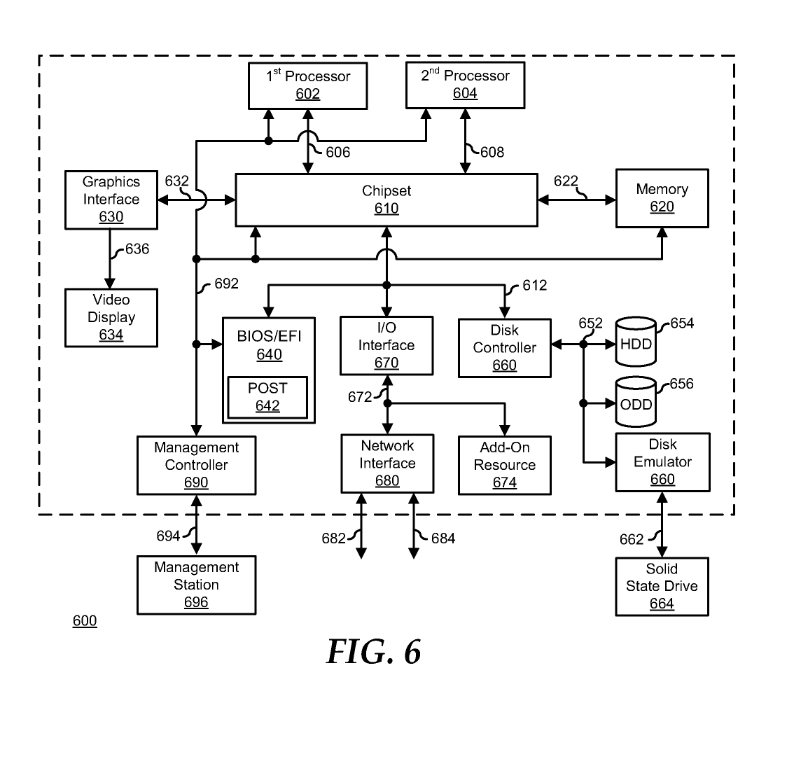

FIG. 6 illustrates a generalized information handling system 600 that can be utilized to carry the methods and to instantiate the devices and modules as described herein. As such, information handling system 600 can include one or more computer-readable storage mediums that include machine-executable code for performing the methods or that are operated on by the devices and modules for carrying out the operations of the devices and modules described herein. Information handling system 600 includes a processor 602 and one or more additional processors 604, a chipset 610, a memory 620, a graphics interface 630, include a basic input and output system/extensible firmware interface (BIOS/EFI) module 640, a disk controller 650, a disk emulator 660, an input/output (I/O) interface 670, a network interface 680, and a management controller (MC) 690. Processor 602 is connected to chipset 610 via processor interface 606, and processor 604 is connected to the chipset via processor interface 608. Memory 620 is connected to chipset 610 via a memory bus 622. Graphics interface 630 is connected to chipset 610 via a graphics interface 632, and provides a video display output 636 to a video display 634. In a particular embodiment, information handling system 600 includes separate memories that are dedicated to each of processors 602 and 604 via separate memory interfaces. An example of memory 620 includes random access memory (RAM) such as static RAM (SRAM), dynamic RAM (DRAM), non-volatile RAM (NV-RAM), or the like, read only memory (ROM), another type of memory, or a combination thereof.

BIOS/EFI module 640, disk controller 650, and I/O interface 670 are connected to chipset 610 via an I/O channel 612. An example of I/O channel 612 includes a Peripheral Component Interconnect (PCI) interface, a PCI-Extended (PCI-X) interface, a high-speed PCI-Express (PCIe) interface, another industry standard or proprietary communication interface, or a combination thereof. Chipset 610 can also include one or more other I/O interfaces, including an Industry Standard Architecture (ISA) interface, a Small Computer Serial Interface (SCSI) interface, an Inter-Integrated Circuit (I²C) interface, a System Packet Interface (SPI), a Universal Serial Bus (USB), another interface, or a combination thereof. BIOS/EFI module 640 includes BIOS/EFI code operable to detect resources within information handling system 600, to provide drivers for the resources, initialize the resources, and access the resources. BIOS/EFI module 640 includes code that operates to detect resources within information handling system 600, to provide drivers for the resources, to initialize the resources, and to access the resources.

Disk controller 650 includes a disk interface 652 that connects the disc controller to a hard disk drive (HDD) 654, to an optical disk drive (ODD) 656, and to disk emulator 660. An example of disk interface 652 includes an Integrated Drive Electronics (IDE) interface, an Advanced Technology Attachment (ATA) such as a parallel ATA (PATA) interface or a serial ATA (SATA) interface, a SCSI interface, a USB interface, a proprietary interface, or a combination thereof. Disk emulator 660 permits a solid-state drive 664 to be coupled to information handling system 600 via an external interface 662. An example of external interface 662 includes a USB interface, an IEEE 1394 (Firewire) interface, a proprietary interface, or a combination thereof. Alternatively, solid-state drive 664 can be disposed within information handling system 600.

I/O interface 670 includes a peripheral interface 672 that connects the I/O interface to an add-on resource 674 and to network interface 680. Peripheral interface 672 can be the same type of interface as I/O channel 612, or can be a different type of interface. As such, I/O interface 670 extends the capacity of I/O channel 612 when peripheral interface 672 and the I/O channel are of the same type, and the I/O interface translates information from a format suitable to the I/O channel to a format suitable to the peripheral channel 672 when they are of a different type. Add-on resource 674 can include a data storage system, an additional graphics interface, a network interface card (NIC), a sound/video processing card, another add-on resource, or a combination thereof. Add-on resource 674 can be on a main circuit board, on separate circuit board or add-in card disposed within information handling system 600, a device that is external to the information handling system, or a combination thereof.

Network interface 680 represents a NIC disposed within information handling system 600, on a main circuit board of the information handling system, integrated onto another component such as chipset 610, in another suitable location, or a combination thereof. Network interface device 680 includes network channels 682 and 684 that provide interfaces to devices that are external to information handling system 600. In a particular embodiment, network channels 682 and 684 are of a different type than peripheral channel 672 and network interface 680 translates information from a format suitable to the peripheral channel to a format suitable to external devices. An example of network channels 682 and 684 includes InfiniBand channels, Fibre Channel channels, Gb Ethernet channels, proprietary channel architectures, or a combination thereof. Network channels 682 and 684 can be coupled to external network resources (not illustrated). The network resource can include another information handling system, a data storage system, another network, a grid management system, another suitable resource, or a combination thereof.

MC 690 is connected to processors 602 and 604, chipset 610, memory 620, and BIOS/EFI module 640 via a system communication bus 692. MC 690 may be on a main circuit board (e.g., a baseboard, a motherboard, or a combination thereof), integrated onto another component such as chipset 610, in another suitable location, or a combination thereof. In a particular embodiment, one or more additional resources of information handling system 600, such as graphics interface 630, video display 634, I/O interface 670, disk controller 650, and network interface 680 are connected to MC 690. MC 690 can be part of an integrated circuit or a chip set within information handling system 600, and can be on a main circuit board, on separate circuit board or add-in card disposed within the information handling system, or a combination thereof. An example of MC 690 includes a baseboard management controller (BMC), an integrated Dell remote access controller (iDRAC), another controller, or a combination thereof. An example of system communication bus 692 includes an inter-integrated circuit (I²C) bus, a system management bus (SMBus), a serial peripheral interface (SPI) bus, a low pin count (LPC) bus, another bus, or a combination thereof.

MC 690 is connected via a network channel 694 to a management station 696 that is external to information handling system 600. Management station 696 operates in conjunction with management controller 690 to provide out-of-band management of information handling system 600. Commands, communications, or other signals are communicated between MC 690 and management station 696 to monitor status of information handling system 600, to control the operations of the resources of the information handling system, and to update the resources. In a particular embodiment, MC 690 is powered by a separate power plane in information handling system 600, so that the MC can be operated while other portions of the information handling system are powered off. In another embodiment, MC 690 is operated during boot of information handling system 600).

Although only a few exemplary embodiments have been described in detail herein, those skilled in the art will readily appreciate that many modifications are possible in the exemplary embodiments without materially departing from the novel teachings and advantages of the embodiments of the present disclosure. Accordingly, all such modifications are intended to be included within the scope of the embodiments of the present disclosure as defined in the following claims. In the claims, means-plus-function clauses are intended to cover the structures described herein as performing the recited function and not only structural equivalents, but also equivalent structures.

The above-disclosed subject matter is to be considered illustrative, and not restrictive, and the appended claims are intended to cover any and all such modifications, enhancements, and other embodiments that fall within the scope of the present invention. Thus, to the maximum extent allowed by law, the scope of the present invention is to be determined by the broadest permissible interpretation of the following claims and their equivalents, and shall not be restricted or limited by the foregoing detailed description.

What is claimed is:

1. A method of providing a case for an information handling system, the method comprising:
placing a first fiber layer into a form, wherein the first fiber layer is prepregnated with a matrix material;
applying a bonding material to the first fiber layer;
placing a bamboo layer into the form on top of the first fiber layer, wherein the bamboo layer is prepregnated with the matrix material;
applying the bonding material to the bamboo layer;
placing a second fiber layer into the form on top of the bamboo layer, wherein the second fiber layer is prepregnated with the matrix material; and
curing the contents of the form to provide a portion of the case.

2. The method of claim 1, further comprising:
prior to placing the first fiber layer into the form:
placing a first cover layer into the form; and
applying the bonding material to the first cover layer; and
after placing the second fiber layer into the form:
applying the bonding material to the second fiber layer; and
placing a second cover layer into the form on top of the second fiber layer.

3. The method of claim 1, wherein the matrix material for the first fiber layer and the second fiber layer is a different matrix material from the matrix material for the bamboo layer.

4. The method of claim 1, wherein the bonding material is the same as the matrix material.

5. The method of claim 1, wherein the bonding material is different from the matrix material.

6. The method of claim 1, wherein the bamboo layer comprises a sheet of bamboo.

7. The method of claim 1, wherein the bamboo layer comprises a woven mat of bamboo strips.

8. The method of claim 1, wherein in curing the contents of the form to provide a portion of the case, the method further comprises:
compressing the contents of the form.

9. The method of claim 1, wherein in curing the contents of the form to provide a portion of the case, the method further comprises:
heating the contents of the form.

10. An information handling system comprising:
a first case piece to receive a mechanism of the information handling system; and
a second case piece to fit to the first case piece and to enclose the mechanism;
wherein the first case piece comprises:
a first cover layer;
a first fiber layer bonded by a bonding material to the first cover layer, wherein the first fiber layer is prepregnated with a matrix material;
a bamboo layer bonded by the bonding material to the first fiber layer, wherein the bamboo layer is prepregnated with the matrix material;
a second fiber layer bonded by the bonding material to the bamboo layer, wherein the second fiber layer is prepregnated with the matrix material; and
a second cover layer bonded by the bonding material to the second fiber layer.

11. The information handling system of claim 10, wherein the matrix material for the first fiber layer and the second fiber layer is a different matrix material from the matrix material for the bamboo layer.

12. The information handling system of claim 10, wherein the bamboo layer comprises a sheet of bamboo.

13. The information handling system of claim 10, wherein the bamboo layer comprises a woven mat of bamboo strips.

14. The information handling system of claim 10, wherein the matrix material comprises a thermoplastic material.

15. The information handling system of claim 10, wherein the matrix material comprises a thermosetting material.

16. A case for an information handling system, the case comprising:
a first cover layer;
a first fiber layer bonded by a bonding material to the first cover layer, wherein the first fiber layer is prepregnated with a matrix material;
a bamboo layer bonded by the bonding material to the first fiber layer, wherein the bamboo layer is prepregnated with the matrix material;
a second fiber layer bonded by the bonding material to the bamboo layer, wherein the second fiber layer is prepregnated with the matrix material; and
a second cover layer bonded by the bonding material to the second fiber layer.

17. The case of claim 16, wherein the bamboo layer comprises a sheet of bamboo.

18. The case of claim 16, wherein the bamboo layer comprises a woven mat of bamboo strips.

19. The case of claim 16, wherein the bonding material is the same as the matrix material.

20. The case of claim 16, wherein the bonding material is different from the matrix material.
